(19) United States
(12) Patent Application Publication
(10) Pub. No.: US 2011/0169105 A1
(43) Pub. Date: Jul. 14, 2011

(54) SEMICONDUCTOR DEVICE AND METHOD FOR MANUFACTURING THE SAME

(75) Inventor: Kazuya OKUBO, Yokohama (JP)

(73) Assignee: FUJITSU SEMICONDUCTOR LIMITED, Yokohama-shi (JP)

(21) Appl. No.: 12/985,842

(22) Filed: Jan. 6, 2011

(30) Foreign Application Priority Data
Jan. 13, 2010 (JP) 2010-4847

(51) Int. Cl. H01L 29/78; H01L 21/336

(52) U.S. Cl. 257/411; 438/287; 257/E29.255; 257/E21.434

(57) ABSTRACT

A method of manufacturing a semiconductor device includes forming a polysilicon pattern, source/drain, and side-wall spacer, epitaxially growing silicide films on the source/drain, epitaxially growing silicon films selectively on the silicide film, removing the polysilicon pattern, forming a gate insulating film and gate electrode.

### CROSS-REFERENCE TO RELATED APPLICATION

This application is based upon and claims the benefit of priority from the prior Japanese Patent Application No. 2010-4847, filed on Jan. 13, 2010, the entire contents of which is incorporated herein by reference.

### FIELD

The present invention relates generally to semiconductor devices and to a method for manufacturing the same.

### BACKGROUND

In general, a MOSFET (Metal-Oxide-Semiconductor Field Effect Transistor) on a silicon substrate includes a gate insulating layer formed of thermally oxidized silicon on the silicon substrate, a polysilicon gate electrode on the gate insulating layer, and source and drain regions formed in the silicon substrate so as to oppose each other with a channel region therebetween under the polysilicon gate electrode.

Recent ultra-high-speed MOSFETs have been improved in terms of operation speed by reducing the gate length, and the thickness of the gate insulating layer has also been reduced in accordance with the scaling law. For a MOS transistor having a gate length of 45 nanometers (nm), for example, the thickness of a thermally oxidized silicon gate insulating layer is reduced to 1 nm or less. However, the reduction of the physical thickness of the gate insulating layer may cause gate leakage current due to a tunneling current passing through the gate insulating layer. This may result in a serious problem.

In order to solve the problem caused by the reduction in gate length, an approach has been made in which nitrogen is introduced to the oxidized silicon film to form a silicon oxynitride (SiON) gate insulating layer having an increased relative dielectric constant. Hence, the effective thickness E_{OT}, which may be called “electrical thickness” or “converted thickness”, is reduced while the physical thickness is maintained to the extent that a tunneling current does not flow. However, an oxidized silicon film has a relative dielectric constant of 3.9 to 4.0, while a silicon nitride film has a relative dielectric constant of about 7 to 8. The use of the intermediate SiON film as the gate insulating layer has a limitation regarding how much the gate length may be reduced.

On the other hand, a metal oxide insulating film, such as that of hafnium oxide (HfO₂) or zirconium oxide (ZrO₂), has an extremely high relative dielectric constant of 20 to 30 and is generally called a high-k dielectric layer. It is expected that by using a high-k dielectric layer as the gate insulating layer, the gate leakage current caused by a tunnel effect may be reduced effectively even in a MOSFET having a still smaller gate length, such as 32 nm, 16 nm, or 8 nm.

However, if a p-type or an n-type polysilicon gate electrode is formed on a gate insulating layer made of such a high-k dielectric layer, a depletion layer is formed in the polysilicon gate electrode, and, then, the effective thickness of the gate insulating layer is undesirably increased. Also, in a MOSFET having a structure in which a polysilicon gate electrode is formed on a high-k dielectric gate insulating layer, the threshold voltage is fixed at a high level, that is, a problem known as so-called fermi level pinning occurs, regardless of whether it is a p channel MOSFET or an n channel MOSFET.

In a metal gate technique using a metal or conductive metal nitride for the gate electrode, a metal gate electrode may be combined with a high-k dielectric gate insulating layer without forming a depletion layer in the gate electrode or causing fermi level pinning. Then, a high-speed MOSFET featuring a high drain current may be provided. Metal gate techniques are disclosed in, for example, Tsuji, Y. et al., Thin Solid Films 516 (2008) 3989-3995; and Fujitsuka, N. et al., Sensors and Actuators A 97-98, (2002), 716-719.

A MOSFET having a metal gate electrode is formed mainly by the following two processes. One is a gate first process. In this process, a metal film intended for a gate electrode is deposited on a silicon substrate with a high-k dielectric gate insulating layer therebetween, as in an ordinary MOSFET manufacturing process. After the metal film is patterned, a source and a drain region are formed by ion implantation. The other is a gate last process. In this process, a polysilicon dummy gate electrode is formed on a silicon substrate with a dummy gate insulating layer of thermally oxidized silicon or the like therebetween, as in a general MOSFET manufacturing process. Then, the source and drain regions are subjected to ion implantation and thermal activation.

### SUMMARY

According to an aspect of the invention, a method of manufacturing a semiconductor device includes forming a polysilicon pattern and source/drain and side-wall spacer, epitaxially growing silicide films on the source/drain, epitaxially growing silicon films selectively on the silicide film, removing the polysilicon pattern, forming a gate insulating film and gate electrode.

The object and advantages of the invention will be realized and attained by at least the feature, elements, and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

FIGS. 1A to 1F are representations illustrating a method for manufacturing a metal gate MOSFET by a gate last process according to the related art;

FIGS. 2A to 2L are representations illustrating a method for manufacturing a metal gate MOSFET according to a first embodiment of the invention;

FIG. 3 is a plot illustrating the relationship between the resistivity of a silicon film and its etch rate;

FIG. 4 is a representation of the structure of a metal gate FET according to a modification of the first embodiment; and

FIGS. 5A to 5F are representations illustrating a method for forming a metal gate MOSFET according to a second embodiment of the invention.

### DESCRIPTION OF EMBODIMENTS

In a gate first process, the previously formed metal gate electrode and gate insulating layer react with each other by heat for activating an impurity element ion-implanted in the source and drain regions, thereby undesirably changing the electrical characteristics of the resulting MOSFET.

In a gate last process, after forming a dummy gate electrode on a silicon substrate and activating the impurity element ion-implanted in the source and drain regions by heat treatment, the dummy gate electrode is covered with an insulating interlayer. The insulating interlayer is polished by chemical mechanical polishing (CMP) to expose the dummy gate electrode. The exposed dummy gate electrode and the underlying dummy gate insulating layer are removed by wet etching. Furthermore, a high-k dielectric layer is formed along the inner wall and the bottom surface of a recess formed in the insulating interlayer by wet etching, and a metal layer is formed over the high-k dielectric layer to fill the recess. Then, the metal layer is polished by CMP until the surface of the insulating interlayer is exposed. Thus, a metal gate electrode filling the recess is formed over the high-k dielectric layer. The high-k dielectric layer underlying the metal gate electrode acts as a gate insulating layer.

In the gate last process, since the gate electrode and the gate insulating layer are not subjected to heat treatment, the electrical characteristics of the MOSFET are not changed; hence, the resulting device may exhibit stable characteristics.

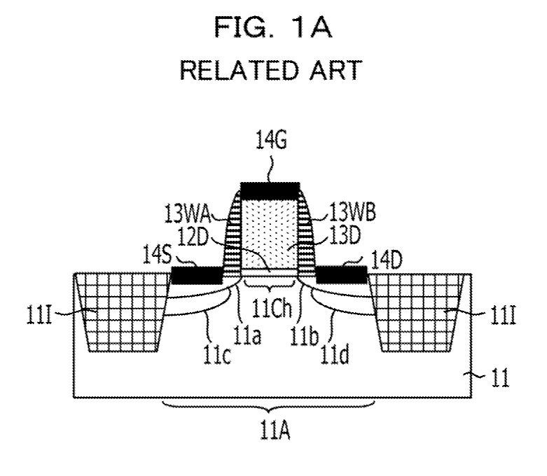

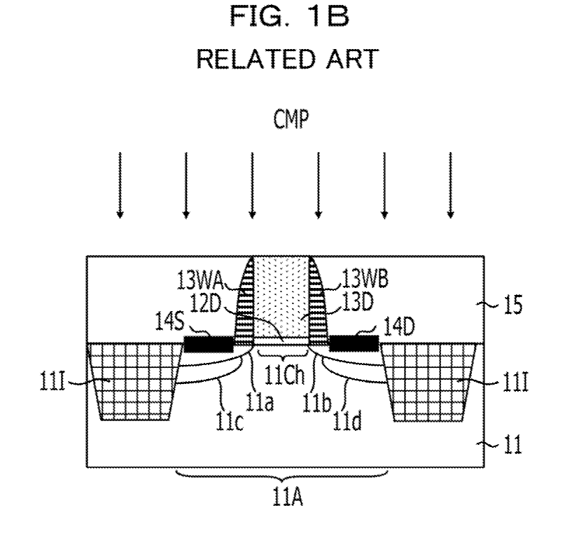

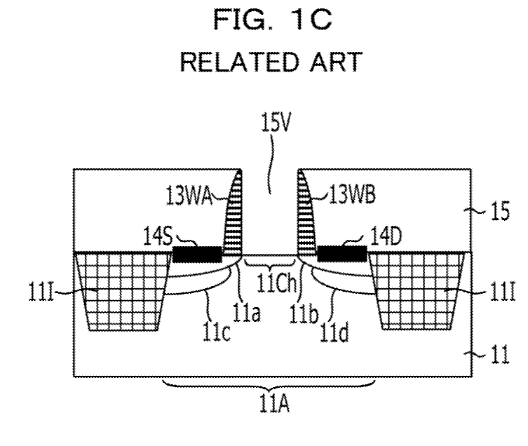

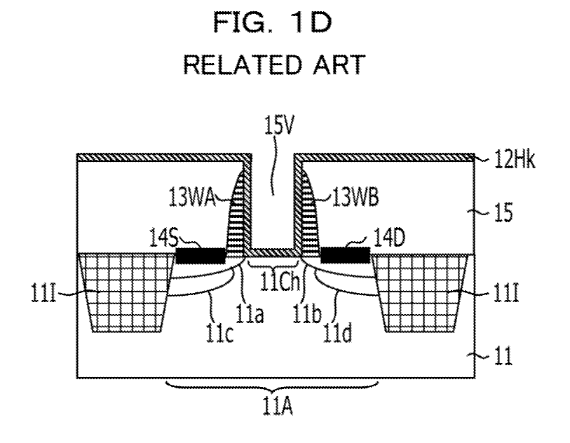

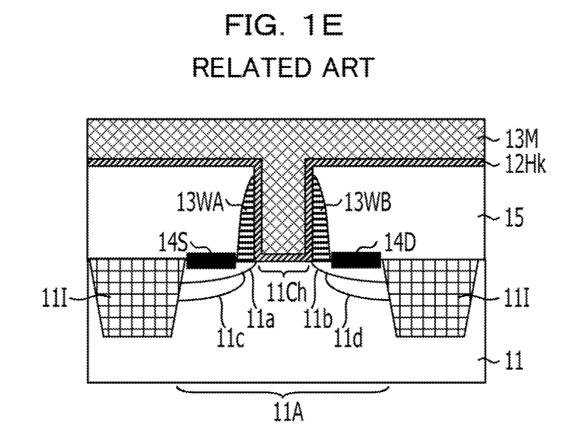

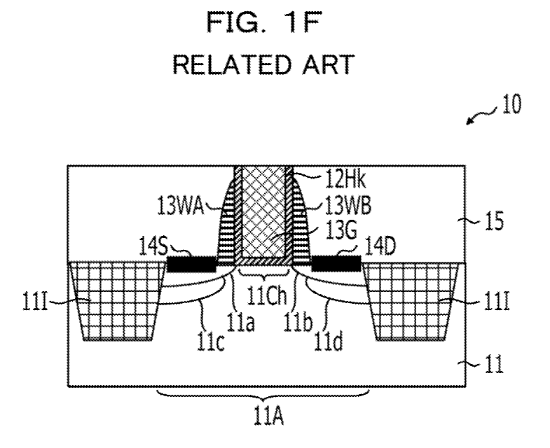

FIGS. 1A to 1F illustrate a method for manufacturing a metal gate MOSFET 10 by a gate last process according to the related art.

As illustrated in FIG. 1A, a dummy gate insulating layer 12D of a thermally oxidized film and a polysilicon dummy gate electrode 13D are formed on a silicon substrate 11 in an element region 11A surrounded by a STI-type element isolation region 11I. Also, a source extension region 11a and a drain extension region 11b are formed in the element region 11A of the silicon substrate 11 so as to oppose each other with a channel region 11Ch therebetween by ion implantation using the dummy gate electrode 13D as a mask.

A first side wall insulating film 13WA and a second side wall insulating film 13WB are formed respectively on a first side wall and a second side wall of the dummy gate electrode 13D, and a source region 11c and a drain region 11d are formed in the element region 11A of the silicon substrate 11.

Further, silicide films 14S and 14D are formed at the surfaces of the source region 11c and the drain region 11d, respectively, by a salicide process. Accompanying the formation of the silicide films 14S and 14D, the dummy gate electrode 13D is covered with a silicide film 14G.

Referring to FIG. 1B, an insulating layer 15 is formed on the silicon substrate 11 so as to cover the dummy gate electrode 13D, and is then polished to expose the dummy gate electrode 13D by CMP. In the operation illustrated in FIG. 1B, the silicide film 14G on the dummy gate electrode 13D is removed by CMP.

Referring to FIG. 1C, the exposed dummy gate electrode 13D and the underlying dummy gate insulating layer 12D are removed by wet etching, and thereby a recess 15V is defined by the side wall insulating films 13WA and 13WB in the insulating layer 15.

Referring to FIG. 1D, a high-k dielectric layer 12Hk of HfO₂, ZrO₂, hafnon (HfSiO₄), zircon (ZrSiO₄) or the like is formed by, for example, chemical vapor deposition (CVD) or atomic layer deposition (ALD) on the insulating layer 15 along the inner surface of the recess 15V so as to cover continuously the inner walls of the side wall insulating films 13WA and 13WB defining the recess 15V and the exposed portion of the silicon substrate 11 corresponding to the channel region 11Ch.

Referring to FIG. 1E, a metal layer 13M is formed of a conductive nitride, such as tin nitride (TiN) or tantalum nitride (TaN), on the insulating layer 15 with the high-k dielectric layer 12Hk therebetween by, for example, sputtering, CVD or ALD, thereby filling the recess 15 volts (V). Referring to FIG. 1F, the high-k dielectric layer 12Hk on the insulating layer 15 is removed by CMP.

Then, a metal gate MOSFET 10 illustrated in FIG. 1F is obtained which includes a metal gate electrode 13G over the gate insulating layer of the high-k dielectric layer 12Hk on the silicon substrate 11 in the channel region 11Ch.

In the method for manufacturing the metal gate MOSFET 10 illustrated in FIGS. 1A to 1F, since heat treatment for activating the impurity element and for forming the silicide films is completed before the operation illustrated in FIG. 1D for forming the high-k dielectric layer 12Hk, the resulting MOSFET may exhibit desired electrical characteristics.

In the gate last process illustrated in FIGS. 1A to 1F, polishing is performed by CMP in the operations illustrated in FIGS. 1B and 1F. When an insulating layer or a metal film is polished by CMP, the polishing rate is locally varied in accordance with the gate length of the element under the insulating layer or the metal film, or the density of arranged elements. For example, in a region on a silicon wafer where elements are arranged at a high density, the polishing rate is increased; and in a region where elements are arranged at a low density, the polishing rate is reduced.

The metal gate electrode 13G has a height of about 100 nm. If such metal gate MOSFETs are formed on a large-diameter silicon wafer having a diameter of, for example, 20 centimeters (cm) or 30 cm by a gate last process, the amount of polishing may be highly precisely controlled over the entire surface of the wafer, regardless of the type and the density of elements to be formed. Accordingly, complicated and difficult measures, such as limiting the type, gate length and layout of MOSFETs to be formed, are required in view of design for manufacture (DFM).

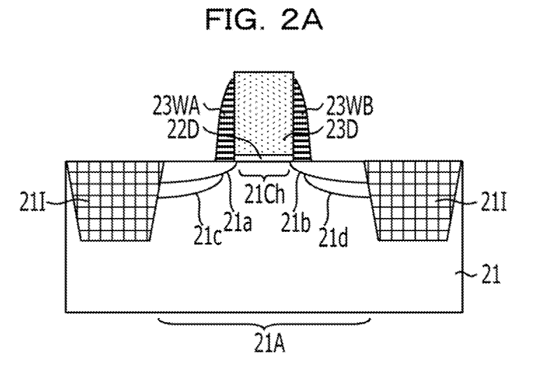

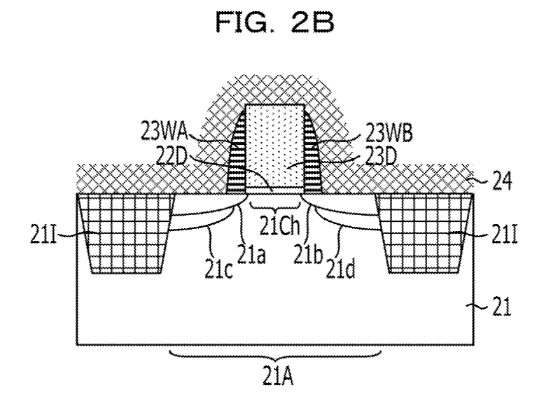

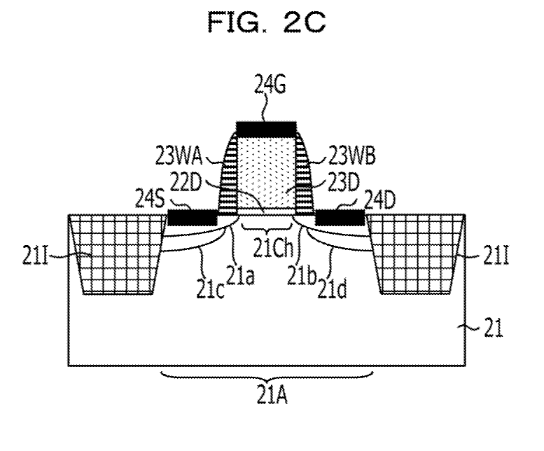

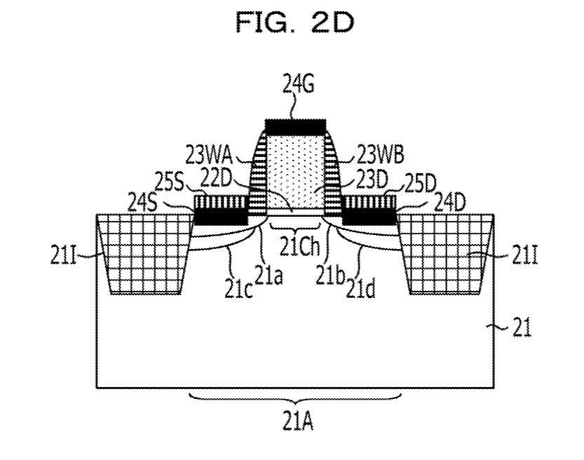

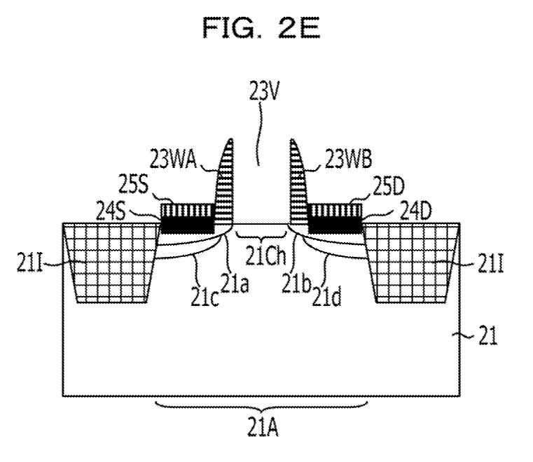

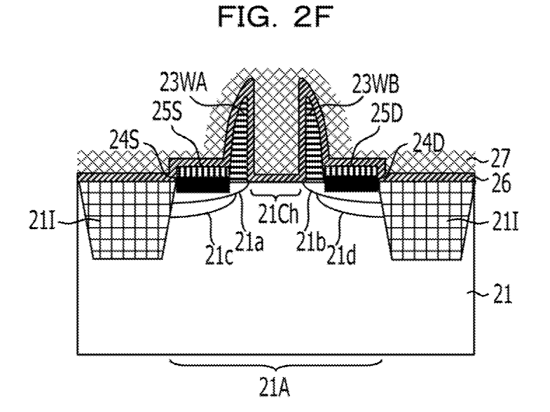

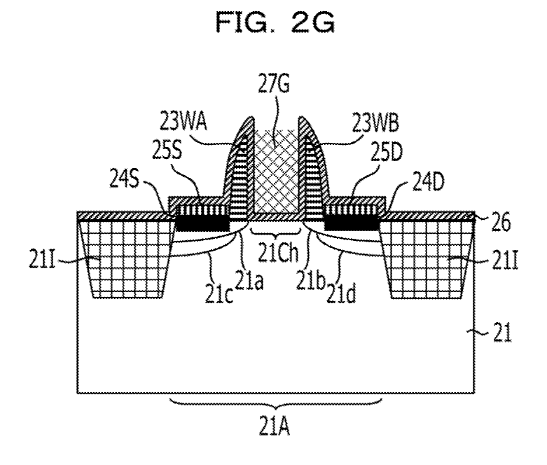

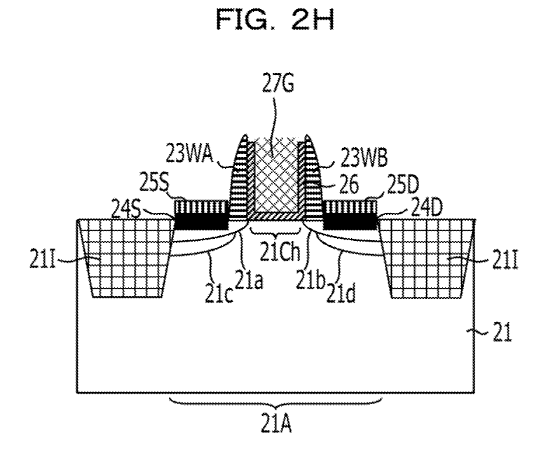

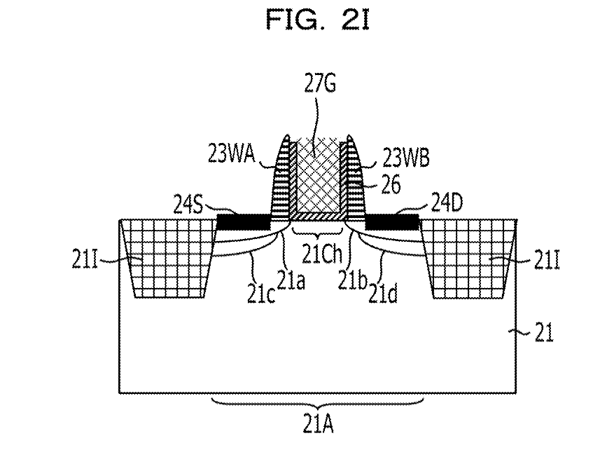

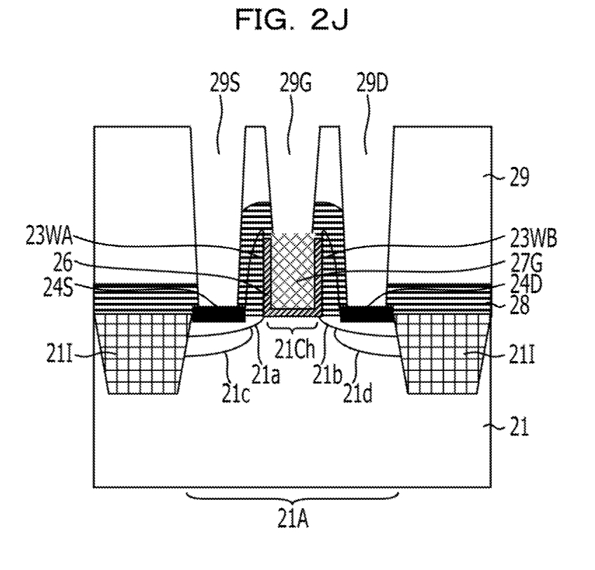

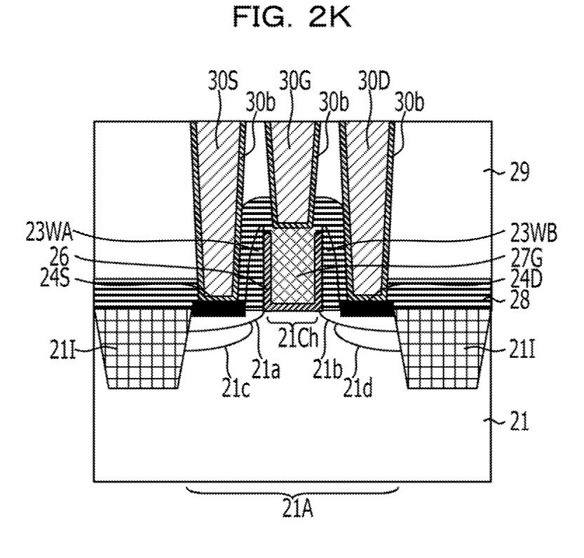

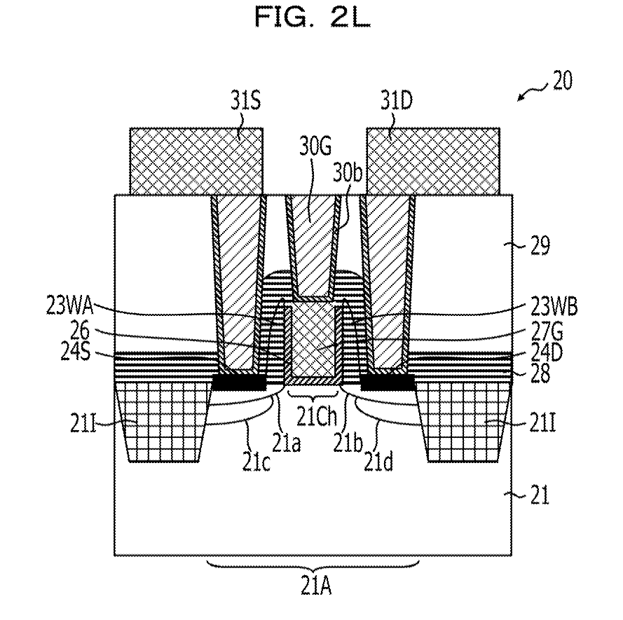

A first embodiment of the invention will now be described with reference to FIGS. 2A to 2L.

Referring now to FIG. 2A, an element region 21A is divided by an STI-type element isolation region 211 in a silicon single-crystal substrate 21 (hereinafter simply referred to as silicon substrate). A polysilicon dummy gate electrode 23D is formed to a height of, for example, 100 nm with a gate length of generally 100 nm or less, such as 45 nm, 32 nm, 16 nm or 8 nm, on the silicon substrate 21 with a dummy gate insulating layer 22D therebetween, corresponding to a channel region 21Ch of the metal gate MOSFET to be formed in a subsequent operation. The dummy gate insulating layer 22D is formed of thermally oxidized silicon, plasma SiON or the like. The dummy gate insulating layer 22D has an appropriate thickness of, for example, about 1.5 to 2.0 nm.

A source extension region 21a and a drain extension region 21b are formed in the element region 21A of the silicon substrate 21 by ion implantation using the dummy gate electrode 22D as a mask. More specifically, for forming an n-type metal gate MOSFET, an n-type impurity element, such as arsenic (As) or phosphorus (P), is implanted into the silicon substrate 21, and for forming a p-type metal gate MOSFET, a p-type impurity element, such as boron (B), is implanted.

For example, when arsenic is implanted to form the source and drain extension regions 21a and 21b, the ion implantation is performed, for example, at an acceleration energy of 1 kiloelectron volt (keV) and a dose of 1×10¹⁵ cm⁻². When boron is implanted to form the source and drain extension regions 21a and 21b, the ion implantation is performed, for example, at an acceleration energy of 0.5 keV and a dose of 1×10¹⁵ cm⁻².

An insulating layer is formed of, for example, SiN or silicon oxide to a thickness of about 100 nm by CVD over the silicon substrate 21 so as to cover the dummy gate electrode 23D. The insulating layer is subjected to anisotropic etching in a direction substantially perpendicular to the surface of the silicon substrate 21. Thus a first side wall insulating film 23WA is formed on the side wall of the dummy gate electrode 23D at the source extension region 21a side, and a second side wall insulating film 23WB is formed on the side wall of the dummy gate electrode 23D at the drain extension 21b region side.

Then, a source and a drain region are formed by ion implantation using the dummy gate electrode 23D and the first and second side wall insulating films 23WA and 23WB as a mask. More specifically, for forming an n-type metal gate MOSFET, an n-type impurity element, such as arsenic or phosphorus, is implanted into the silicon substrate 21, and for forming a p-type metal gate MOSFET, a p-type impurity element, such as boron, is implanted into the silicon substrate 21. The source region 21c is formed toward the outside of the first side wall insulating film 23WA under the source extension region 21a, and the drain region 21d is formed toward the outside of the second side wall insulating film 23WB under the drain extension region 21b.

For example, when phosphorus is implanted for forming the source and drain regions 21c and 21d, the ion implantation is performed, for example, at an acceleration energy of 8 keV and a dose of 1×10¹⁶ cm⁻², and the resulting source and drain regions 21c and 21d contain 7×10¹⁶ cm⁻³ of phosphorus as an impurity. When boron is implanted for forming the source and drain regions 21c and 21d, the ion implantation is performed, for example, at an acceleration energy of 5 keV and a dose of 5×10¹⁵ cm⁻², and the resulting source and drain regions 21c and 21d contain 2×10¹⁷ cm⁻³ of boron as an impurity.

After the ion implantation for the source and drain regions 21c and 21d, the silicon substrate 21 is heat-treated at a temperature of, for example, 1025° Celsius (C) for 0 to 3 seconds to activate the impurity element implanted in the source and drain regions 21c and 21d and the source and drain extension regions 21a and 21b.

In the ion implantation for the source and drain regions 21c and 21d, the dummy gate electrode 23D is also subjected to the ion implantation, and then the polysilicon film of the dummy gate electrode 23D is doped with an n-type or a p-type impurity to a high concentration comparable to the concentration in the source and drain regions 21c and 21d.

Subsequently, after the upper surfaces of the source region 21c, the drain region 21d and the dummy gate electrode 23D are treated with hydrofluoric acid to remove the naturally oxidized layers, a metal layer 24 is formed of nickel (Ni), cobalt (Co) or the like to a thickness of, for example, 5 to 10 nm over the entire surface of the structure illustrated in FIG. 2A by sputtering so as to cover continuously the upper surfaces of the source region 21c, the drain region 21d, the side wall insulating films 23WA and 23WB, and the dummy gate electrode 23D, as illustrated in FIG. 2B. The resulting structure is then subjected to rapid heat treatment at a temperature of 750 to 850° C. for about 30 seconds in an atmosphere of a reducing gas, such as silane (SiH₄) gas, or an inert gas, such as nitrogen gas. Then, low-resistance silicide films 24S, 24D and 24G are formed so as to have a thickness of, for example, 20 nm at the surfaces in contact with the metal layer 24 over the source region 21c, the drain region 21d and the polysilicon dummy gate electrode 23D, as illustrated in FIG. 2C. After forming the silicide films, the unreacted portion of the metal layer 24 is removed as illustrated in FIG. 2C by etching using a so-called SPM (sulfuric acid/hydrogen peroxide mixture), which is a mixed solution containing sulfuric acid (H₂SO₄), hydrogen peroxide (H₂O₂) and water (H₂O). The volume ratio of sulfuric acid to hydrogen peroxide water in the SPM may be 3:1, and the etching is preferably performed at 80° C. for about 30 seconds. However, the etchant for removing the unreacted portion of the metal layer is not limited to the SPM, and, for example, a mixed solution called an HPM may be used which contains hydrochloric acid (HCl), hydrogen peroxide and water.

In this instance, it may be note that the material of the metal layer 24 is selected so that the silicide film to be formed lattice-matches with silicon. For example, a nickel silicide film having a composition of NiSi₂ formed from a nickel metal layer 24 has a CaF₂ structure (face-centered cubic lattice) with a lattice constant of 5.406 angstroms (Å). This lattice constant is 0.5% smaller than the lattice constant (5.431 Å) of silicon crystal having a diamond structure being the same face-centered cubic lattice, and accordingly NiSi₂ may favorably lattice-match with silicon.

A cobalt silicide film having a composition of CoSi₂ formed from a cobalt metal layer 24 has a CaF₂ structure with a lattice constant of 5.353 Å. This lattice constant is 1.4% smaller than the lattice constant (5.431 Å) of silicon crystal, and accordingly CoSi₂ may lattice-match with silicon comparably favorably.

Accordingly, in the structure illustrated in FIG. 2C, the silicide films 24S and 24D overlying the source region 21c and the drain region 21d epitaxially grow on the silicon substrate and have a single-crystal structure, as long as having a thickness smaller than or equal to the critical thickness (about 100 nm). On the other hand, the silicide film 24G overlying the dummy gate electrode 23D becomes a polycrystalline film having a polycrystalline structure because the underlying layer of the silicide film 24G is polycrystalline.

Such a single-crystal silicide film formed on a silicon single-crystal substrate has been disclosed in the above-cited non-patent document of Tsuji, Y.

In the operation illustrated in FIG. 2B, a TiN protective film (not illustrated) may be formed to a thickness of 5 to 30 nm on the surface of the metal layer 24. In the present embodiment, the metal layer 24 may be formed of a nickel alloy, such as NiPt, NiPd, or NiTa, or a similar cobalt alloy.

Referring to FIG. 2D, single-crystal silicon films 25S and 25D are epitaxially grown selectively on the single-crystal silicide films 24S and 24D respectively by CVD. The single-crystal silicon films 25S and 25D preferably have a thickness of about 2 to 5 nm, being not more than the critical thickness.

Selective growth of the single-crystal silicon films 25S and 25D is performed using silane (SiH₄), dichlorosilane (SiH₂Cl₂) or trichlorosilane (SiHCl₃) as the silicon source gas. Preferably, the source gas contains an etching gas, such as hydrogen chloride (HCl) or chlorine (Cl₂), for selective growth. When, for example, silane gas is used as the source gas, the selective growth of the single-crystal silicon films may be performed at a substrate temperature of 450 to 470° C., a total pressure of 5 to 130 Pa and a silane gas partial pressure of 1 to 5 Pa. Under these conditions, a silicon film does not substantially grow on the silicide film 24G on the polycrystalline dummy gate electrode 23D.

The selective growth of the single-crystal silicon films 25S and 25D in the operation illustrated in FIG. 2D is performed without doping the single-crystal silicon films 25S and 25D with an impurity element, such as arsenic, phosphorus, or boron. Then, the impurity concentration in the single-crystal silicon films 25S and 25D is about 1×10¹⁷ cm⁻³ or less. As described later, an n-type impurity element, such as arsenic or phosphorus, is preferably implanted to a concentration of less than 7×10¹⁶ cm⁻³, or a p-type impurity element, such as boron, is preferably implanted to a concentration of less than 2×10¹⁷ cm⁻³. The thus formed single-crystal silicon films 25S and 25D have a high resistivity of more than 0.1 Ωcm according to such a low impurity concentration.

The selective growth of the single-crystal silicon films 25S and 25D may be performed by alternately repeating crystal growth using an above-mentioned silicon source gas and etching using an etching gas several times. Alternatively, after crystal growth using a silicon source gas, etching may be performed using an etching gas.

In the present embodiment, by adding an etching gas to the silicon source gas for forming the single-crystal silicon films 25S and 25D, or by performing etching in the operation for forming the single-crystal silicon films 25S and 25D, a polysilicon film may be immediately removed even if the polysilicon film is formed on the polycrystalline silicide film 24G or the side wall insulating films 23WA and 23WB. This is because the polysilicon film is thinner and more easily etched than the single-crystal silicon films 25S and 25D.

Referring to FIG. 2E, the silicide film 24G and the dummy gate electrode 23D, and further the underlying dummy gate insulating layer 22D are selectively removed by wet etching so as to form a recess 23V exposing the surface of the silicon substrate 21 between the first and second side wall insulating films 23WA and 23WB.

More specifically, the silicide film 24G of the structure illustrated in FIG. 2D is etched with aqua regia, which is a mixture containing of nitric acid and hydrochloric acid in a volume ratio of 1:3. In this operation, the single-crystal silicide films 24S and 24D over the source region 21c and the drain region 21d are protected by the single-crystal silicon films 25S and 25D, thus prevented from being etched.

After the removal of the silicide film 24G, the dummy gate electrode 23D and the dummy gate insulating layer 22D are removed by selective etching using a fluoronitric etchant containing hydrofluoric acid (HF) and nitric acid (HNO₃). Etching using a hydrofluoric etchant is stopped when the surface of the silicon substrate 21 has been exposed at the bottom of the recess 23V. The fluoronitric etchant may further contain acetic acid (CH₃COOH).

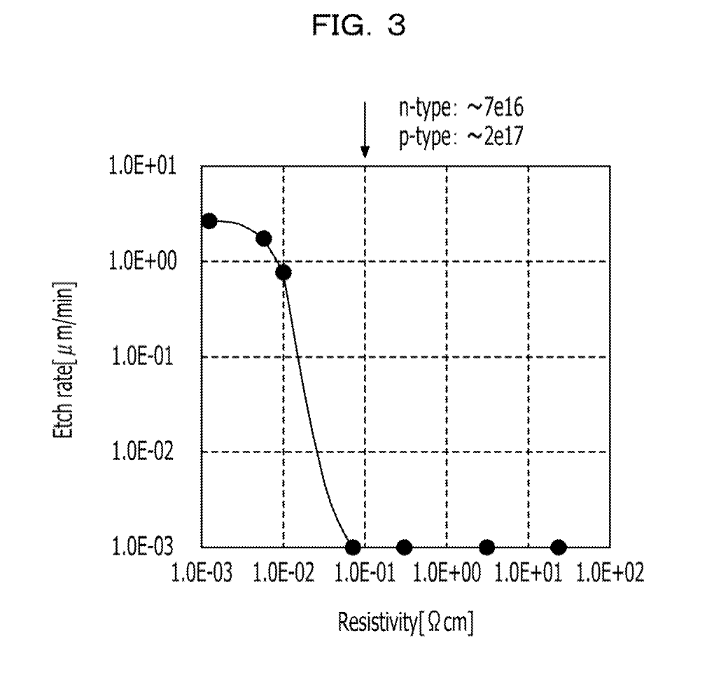

FIG. 3 is a plot illustrating the relationship between the etch rate and the resistivity of the single-crystal silicon film according to the above-cited non-patent document of Fujitsuka, N. In this experiment, the surface of a silicon wafer was etched with a mixed etchant containing HF, HNO₃, and CH₃COOH in a volume ratio of 1:3:8.

FIG. 3 shows that single-crystal silicon films having resistivities of more than 1×10⁻¹ (=0.1) Ωcm are etched at a rate of 1×10⁻³ micrometers (μm)/min or less and are hardly etched, while single-crystal silicon films having resistivities of 0.1 Ωcm or less sharply increase the etch rate as the resistivity is reduced, and that, for example, a single-crystal silicon film having a resistivity of 0.01 Ωcm is etched at a rate of more than 1 μm/min. The silicon film having a resistivity of 0.01 fΩcm corresponds to silicon films doped with an n-type impurity, such as arsenic or phosphorus, to an impurity concentration of 7×10¹⁶ cm⁻³, and silicon films doped with a p-type impurity, such as boron, to an impurity concentration of 2×10¹⁷ cm⁻³.

In the removal of the dummy gate electrode 23D, which is made of polysilicon, by etching in the operation illustrated in FIG. 2E, the dummy gate electrode 23D has been doped to a high concentration when the source region 21c and the drain region 21d have been formed. For example, a dummy gate electrode 23D doped with an n-type impurity element has an impurity concentration of more than 7×10¹⁶ cm⁻³, and a dummy gate electrode 23D doped with a p-type impurity element has an impurity concentration of more than 2×10¹⁷ cm⁻³. Accordingly, the dummy gate electrode 23D, which has a low resistivity of 0.1 Ω/cm or less, may be etched at a high rate, as illustrated in FIG. 3. Since the dummy gate electrode 23D is made of polysilicon, it is etched at a higher rate than the etch rate illustrated in FIG. 3.

On the other hand, the silicon single-crystal films 25S and 25D are not doped and has a resistivity of more than 0.1 Ωcm, containing a n-type impurity element of less than 7×10¹⁶ cm⁻³ or a p-type impurity element of less than 2×10¹⁷ cm⁻³. Accordingly, the silicon single-crystal films 25S and 25D are hardly etched and act as an effective mask.

Since the surface of the silicon substrate 21 has a high resistivity of more than 0.1 Ω/cm and a low impurity concentration according to the high resistivity, the etching is spontaneously stopped when the surface of the silicon substrate 21 has been exposed in the recess 23V.

If polysilicon films are formed discontinuously, for example, in an island manner on the polycrystalline silicide film 24G in the operation illustrated in FIG. 2D, the polysilicon films may be removed by lift-off simultaneously with the removal of the polycrystalline silicide film 24G in the operation illustrated in FIG. 2E.

Referring to FIG. 2F, a high-k dielectric layer 26 is formed to a uniform thickness over the structure illustrated in FIG. 2E, and a metal layer 27 is further formed over the high-k dielectric layer 26 to fill the recess 23V.

More specifically, the high-k dielectric layer 26 may be formed of a metal oxide, such as HfO₂, ZrO₂, or Y₂O₃, or a silicate or aluminate of hafnium, zirconium, yttrium or the like, to a thickness of about 1 to 3 nanometers (nm) by ALD or CVD. Thus the side wall insulating films 23WA and 23WB and the silicon substrate 21 exposed at the bottom of the recess 23V are continuously covered with the high-k dielectric layer 26. The high-k dielectric layer 26 may be further doped with nitrogen. If the high-k dielectric layer 26 is made of HfO₂, the HfO₂ layer may contain Zr, and if it is made of ZrO₂, the ZrO₂ layer may contain Hf.

The metal layer 27 may be made of a metal, such as Ti or Ta, or a conductive metal nitride, such as TiN or TaN. The material of the metal layer may be doped with a small amount of silicon (Si) or carbon (C) so that the work function in a bulk state is about 4.3 eV for an n-type MOSFET, or about 4.9 eV for a p-type MOSFET. The metal layer 27 may have a composition of, for example, TiSiN, TaC, TaCN, or TaSiN. The metal layer 27 may be made of a metal or metal nitride including at least one element such as, for example, nickel, cobalt, titanium, tantalum, zirconium, hafnium, tungsten, platinum, chromium, palladium, rhenium, vanadium, and niobium.

While the metal layer 27 may be formed by PVD, such as sputtering, it may be formed by ALD or CVD.

Referring to FIG. 2G, The metal layer 27 other than the portion filling the recess 23V is removed with a chemical solution, such as APM (mixed solution of ammonia and hydrogen peroxide) or HPM, and the metal layer 27 remaining in the recess 23V is used as a metal gate electrode 27G. In this instance, the high-k dielectric layer 26 directly under the metal gate electrode 27G acts as the high-k gate insulating layer.

The wet etching of the metal layer in the operation illustrated in FIG. 2G is controlled by time, and is stopped at a time when the high-k dielectric layer 26 has been exposed over the silicon single-crystal films 25S and 25D and the element isolation region 211.

For etching a TiN metal layer 27 with APM (etchant containing ammonia (NH₄OH), hydrogen peroxide (H₂O₂) and water (H₂O) in a value ratio of 1:1:10), the metal layer 27 may be etched to a depth of 20 nm at a temperature of 65° C. for 5 minutes. Alternatively, the metal layer 27 may be dry-etched using a chlorine-based gas (such as Cl₂ and BCl₃).

Referring to FIG. 2H, the structure illustrated in FIG. 2G is treated with hydrofluoric acid to remove the exposed portion of the high-k dielectric layer 26 so that only the portion in contact with the metal gate electrode 27G remains. Furthermore, in the present embodiment, the single-crystal silicon films 25S and 25D are removed by wet etching to expose the single-crystal silicide films 24S and 24D, as illustrated in FIG. 2I.

A SiN layer 28 is formed to a thickness of, for example, 50 nm as an etching stopper over the structure illustrated in FIG. 2I by CVD, and an insulating interlayer 29 is formed to a thickness of, for example, 600 nm over the SiN layer 28 by CVD.

In the operation illustrated in FIG. 2I, the insulating interlayer 29 is planarized by CMP, and via holes 29S, 29D and 29G are formed to expose the single-crystal silicide films 24S and 24D and the metal gate electrode 27G by photolithography.

More specifically, the etching for forming the via holes 29S, 29D and 29G in the insulating interlayer 29 stops spontaneously at the time when the SiN layer 28 acting as an etching stopper has been exposed. Then, the etching stopper 28 is etched under different etching conditions until the silicide films 24S and 24D are exposed in the via holes 29S and 29D and the metal gate electrode 27G is exposed in the via hole 29G.

Referring to FIG. 2K, a TiN barrier layer 30b is formed to a thickness of 5 nm over the inner surfaces of the via holes 29S, 29D and 29G, and then a tungsten layer (not illustrated) is deposited to a thickness of, for example, 100 nm. The tungsten layer is polished by CMP until the upper surface of the insulating interlayer 29 is exposed, thus forming via plugs 30S, 30D and 30G.

Referring to FIG. 2L, wiring patterns 31S and 31D are formed on the insulating interlayer 29 to complete a metal gate MOSFET 20.

In the present embodiment, the metal gate electrode 27G may be formed by a gate last process without applying CMP, and a metal gate MOSFET may be manufactured with a high yield. Although the present embodiment performs CMP in the operations illustrated in FIGS. 23 and 2K, the yield is not reduced even if unevenness or dishing is caused to some extent in the insulating interlayer 29 by polishing, because the insulating interlayer 29 to be polished has a thickness as large as 600 nm.

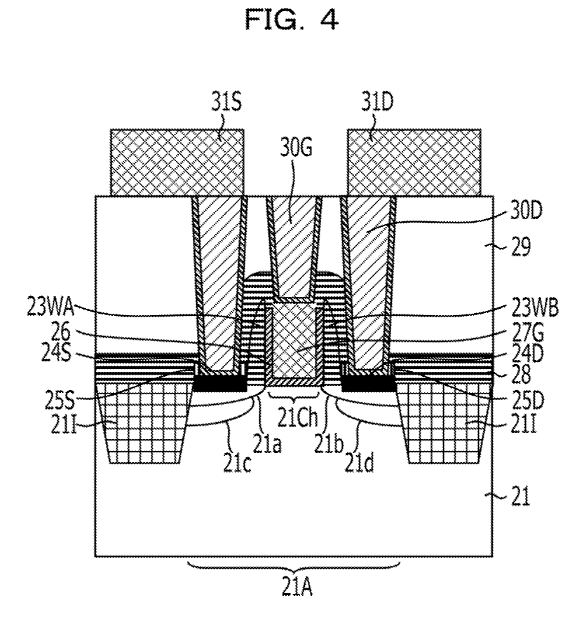

The operation illustrated in FIG. 2I may be omitted so that the single-crystal silicon films 25S and 25D remain in the structure illustrated in FIG. 2H. In this instance, the via plugs 30S and 30G of the resulting metal gate MOSFET extend through the single-crystal silicon films 25S and 25D to come in contact with the single-crystal silicide films 24S and 24D, respectively, as illustrated in FIG. 4.

In either of the metal gate MOSFETs illustrated in FIG. 2L and FIG. 4, the high-k dielectric layer 26 causes a parasitic capacitance, and is preferably removed from the region around the via holes 29S and 29D in which the via plugs 30S and 30D are to be formed.

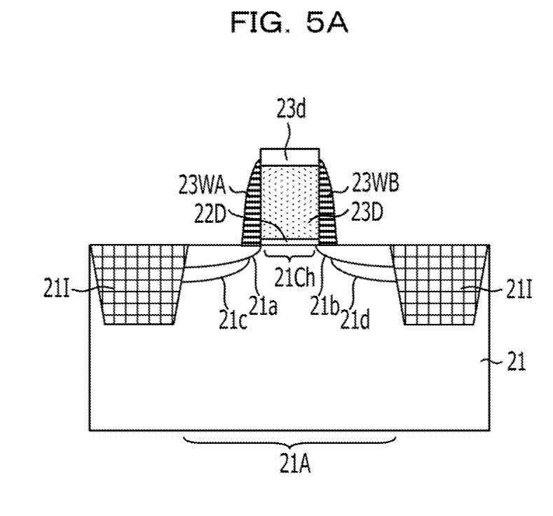

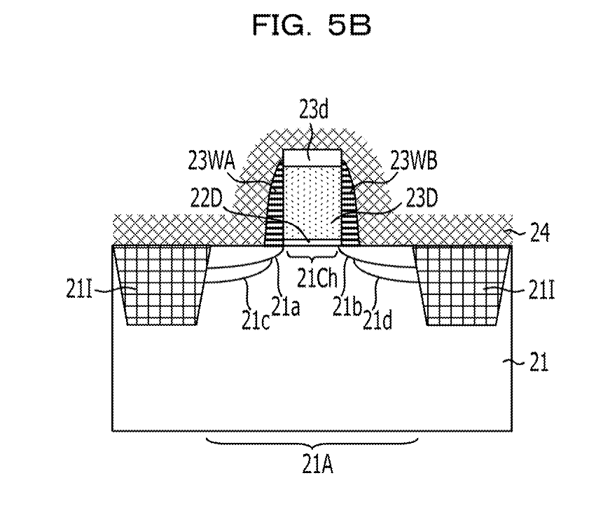

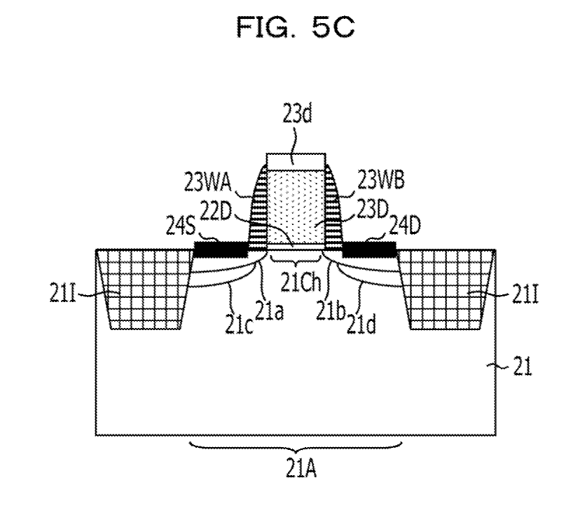

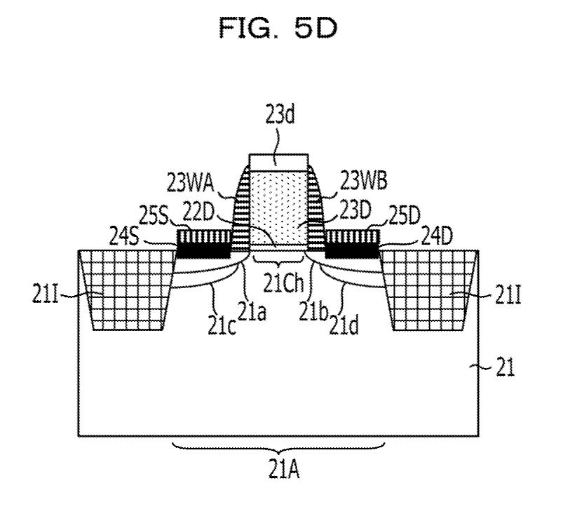

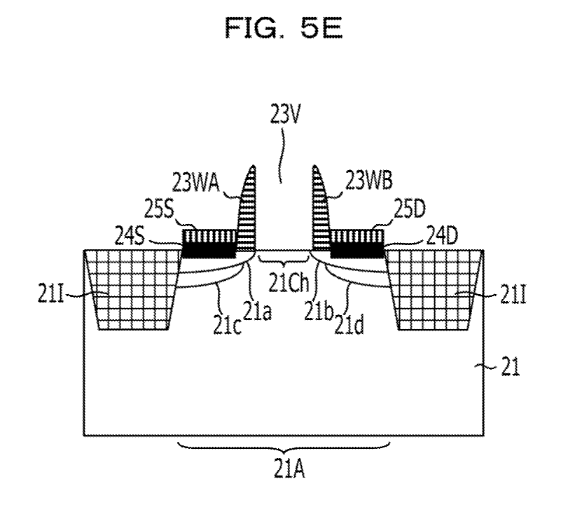

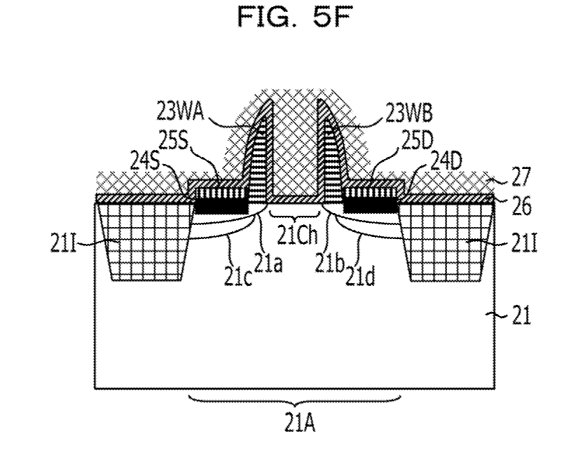

FIGS. 5A to 5C are representations illustrating a method for manufacturing a semiconductor device according to a second embodiment of the invention. The same parts in the figures as in the foregoing description are designated by the same reference numerals and the same description will be omitted.

In this embodiment, the structure illustrated in FIG. 2A is replaced with the structure illustrated in FIG. 5A having a cap layer 23d of an amorphous insulating material on the dummy polysilicon gate electrode 23D. Preferably, the cap layer 23d is formed to a thickness of, for example, 5 to 10 nm by CVD, and has different etching selectivity from the side wall insulating films 23WA and 23WB. For example, if the side wall insulating films 23WA and 23WB are made of SiN, the cap layer 23d is preferably made of silicon oxide. If the side wall insulating films 23WA and 23WB are made of silicon oxide, the cap layer 23d is preferably made of SiN.

Referring to FIG. 5B, a metal layer 24 of nickel, cobalt or the like is formed to a thickness of 5 to 10 nm over the structure illustrated in FIG. 5A in the same manner as in the first embodiment, and is subsequently heat-treated at a temperature of 750 to 850° C. Thus single-crystal silicide films 24S and 24D are formed over the source region 21c and the drain region 21d, respectively, as illustrated in FIG. 5C. In FIG. 5C, the unreacted portion of the metal layer 24 is removed in the same manner as in the operation illustrated in FIG. 2C by etching. Since the amorphous insulating layer 23d is provided on the dummy polysilicon gate electrode 23D in the present embodiment, a silicide film is not formed on the dummy polysilicon gate electrode 23D.

Referring to FIG. 5D, single-crystal silicon films 25S and 25D are epitaxially formed to a thickness of 2 to 5 nm on the single-crystal silicide films 24S and 24D illustrated in FIG. 5C in the same manner as in the first embodiment. In the present embodiment, however, a silicon film hardly grows on the dummy polysilicon gate electrode 23D because the amorphous insulating layer 23d is provided on the dummy polysilicon gate electrode 23D. The single-crystal silicon films 25S and 25D are not doped as in the first embodiment, or are slightly doped. Then, the resulting single-crystal silicon films 25A and 25D have a resistivity of 0.1 Ωcm or more. If an n-type impurity element, such as As or P, is implanted, the resistivity is 7×10¹⁶ cm⁻³ or less. If a p-type impurity element, such as B, is implanted, the resistivity is 2×10¹⁷ cm⁻³ or less.

Referring to FIG. 5E, the amorphous insulating layer 23d, the dummy polysilicon gate electrode 23D and further the dummy gate insulating layer 22D are removed to form a recess 23V between the first and second side wall insulating films 23WA and 23WB by selective etching using the single-crystal silicon films 25S and 25D as a mask. In the recess 23V, the surface of the silicon substrate 21 is exposed. If the amorphous insulating layer 23d is made of silicon oxide and the first and second side wall insulating films 23WA and 23WB are made of SiN, the selective etching in the operation illustrated in FIG. 5E may be performed using a fluoronitric etchant, such as an aqueous solution containing nitric acid and hydrofluoric acid, in the same manner as in the first embodiment. In this instance, the amorphous insulating layer 23d, the dummy insulating layer 23D and the dummy gate insulating layer 22D may be removed at one time. The fluoronitric etchant may further contain acetic acid.

Referring to FIG. 5F, a high-k dielectric layer 26 is formed to a uniform thickness over the structure illustrated in FIG. 5E, and a metal layer 27 is further formed on the high-k dielectric layer 26 to fill the recess 23V, in the same manner as in the operation illustrated in FIG. 2F. Furthermore, the same operations as in FIGS. 2G to 2L are performed to complete a metal gate MOSFET 20 illustrated in FIG. 2L.

In the present embodiment, the single-crystal silicon films 25S and 25D may be left, as in the modification illustrated in FIG. 4.

All examples and conditional language recited herein are intended for pedagogical purposes to aid the reader in understanding the invention and the concepts contributed by the inventor to furthering the art, and are to be construed as being without limitation to such specifically recited examples and conditions. Although the embodiments of the present inventions have been described in detail, it should be understood that various changes, substitutions, and alterations could be made hereto without departing from the spirit and scope of the invention.

What is claimed is:

1. A method of manufacturing a semiconductor device comprising:
forming an insulating layer over a silicon substrate;
forming a polysilicon pattern over the insulating layer;
forming a source extension region and a drain extension region in the silicon substrate by implanting a first impurity element into the silicon substrate using the polysilicon pattern as a mask;
forming a first side wall insulating film and a second side wall insulating film on side walls of the polysilicon pattern;
forming a source region and a drain region in the silicon substrate by implanting a second impurity element into the silicon substrate using the polysilicon pattern and the first and second side wall insulating films as a mask;
activating the first impurity element and the second impurity element by heat treatment;
epitaxially growing a first silicide film and a second silicide film over the source region and the drain region, respectively;
epitaxially growing a first silicon film and a second silicon film selectively on the first silicide film and the second silicide film, respectively;
selectively removing the polysilicon pattern and the insulating layer using the first silicide film and the second silicide film as a mask;
forming a dielectric layer over the silicon substrate so as to substantially continuously cover the surfaces of the first side wall insulating film, the second side wall insulating film and the silicon substrate;
forming a conductive layer including a metal or a conductive metal nitride on the dielectric layer; and
forming a gate electrode by etching the conductive layer so as to remain between the first side wall insulating film and the second side wall insulating film.

2. The method according to claim 1, wherein in the epitaxially growing the first silicide film and the second silicide film, a polycrystalline silicide film is formed on the polysilicon pattern.

3. The method according to claim 1, further comprising: forming an amorphous insulating layer over the polysilicon pattern, wherein the second impurity element is implanted into the polysilicon pattern through the amorphous insulating layer in the forming of the source region and the drain region.

4. The method according to claim 1, wherein the second impurity element is arsenic, phosphorus or boron, and the forming of the source region and the drain region is performed by implanting the second impurity element so that the polysilicon pattern includes 7×10¹⁶ cm⁻³ or more of arsenic or phosphorus, or 2×10¹⁷ cm⁻³ or more of boron.

5. The method according to claim 1, wherein the first silicon film and the second silicon film formed in the epitaxially growing of the first silicon film and the second silicon film includes less than 7×10¹⁶ cm⁻³ of arsenic or phosphorus, or less than 2×10¹⁷ cm⁻³ of boron.

6. The method according to claim 1, wherein the first silicon film and the second silicon film formed in the epitaxially growing of the first silicon film and the second silicon film have a resistivity of more than 0.1 Ωcm.

7. The method according to claim 1, further comprising:
forming an insulating interlayer covering the gate electrode over the silicon substrate;
forming a first via hole and a second via hole in the insulating interlayer to expose the source region and the drain region, respectively; and
forming a first via plug in the first via hole and a second via plug in the second via hole.

8. The method according to claim 7, wherein the first via hole and the second via hole are formed so as to pass through the first silicon film and the second silicon film, respectively, and the first via plug and the second via plug are formed so as to contact with the first silicide film and the second silicide film, respectively.

9. The method according to claim 1, further comprising:
removing the first silicon film and the second silicon film;
forming an insulating interlayer covering the gate electrode over the silicon substrate;
forming a first via hole and a second via hole in the insulating interlayer to expose the source region and the drain region, respectively; and
forming a first via plug in the first via hole and a second via plug in the second via hole.

10. A semiconductor device comprising:
a silicon substrate;
a gate insulating layer disposed on the silicon substrate;
a gate electrode including a metal or a conductive metal nitride disposed on the gate insulating layer;
a source region in the silicon substrate;
a drain region in the silicon substrate;
a first silicide film over the source region;
a second silicide film over the drain region;
a first silicon film on the first silicide film; and
a second silicon film on the second silicide film.

11. The semiconductor device according to claim 10, further comprising:
an insulating interlayer covering the gate electrode; and
a first via plug, a second via plug and a third via plug formed in the insulating interlayer, the first via plug reaching the gate electrode, the second via plug reaching the source region and being in contact with the first silicide film, the third via plug reaching the drain region and being in contact with the second silicide film.

12. The semiconductor device according to claim 10, wherein the first silicon film and the second silicon film include less than 7×10¹⁶ cm⁻³ of arsenic or phosphorus or less than 2×10¹⁶ cm⁻³ of boron.

13. The semiconductor device according to claim 10, wherein the first silicon film and the second silicon film have a resistivity of 0.1 Ωcm or more.

14. The semiconductor device according to claim 10, wherein the first silicon film and the second silicon each have a thickness of 2 nm to 5 nm.

15. The semiconductor device according to claim 10, wherein the first silicide film and the second silicide film are made of NiSi₂ or CoSi₂.

16. The semiconductor device according to claim 10, wherein the gate insulating layer contains a compound selected from the group consisting of oxides, silicates and aluminates of hafnium, zinc and yttrium.

17. The semiconductor device according to claim 16, wherein the gate insulating layer further includes nitrogen.

18. The semiconductor device according to claim 10, wherein the gate electrode is made of a metal or metal nitride containing at least one element selected from the group consisting of nickel, cobalt, titanium, tantalum, zirconium, hafnium, tungsten, platinum, chromium, palladium, rhenium, vanadium, and niobium.
